(19) United States
(12) Patent Application Publication
(10) Pub. No.: US 2026/0164994 A1
(43) Pub. Date: Jun. 11, 2026

(54) DISPLAY APPARATUS, MANUFACTURING APPARATUS OF DISPLAY APPARATUS, METHOD OF MANUFACTURING DISPLAY APPARATUS, AND ELECTRONIC DEVICE

(71) Applicant: Samsung Display Co., Ltd., Yongin-si (KR)

(72) Inventor: Kiyong Park, Yongin-si (KR)

(21) Appl. No.: 19/285,491

(22) Filed: Jul. 30, 2025

(30) Foreign Application Priority Data
Dec. 5, 2024 (KR) 10-2024-0179691

(51) Int. Cl. H10K 59/80; H10K 59/12

(52) U.S. Cl. CPC H10K 59/873; H10K 59/1201

(57) ABSTRACT

Provided are a display apparatus, a manufacturing apparatus of the display apparatus, a method of manufacturing the display apparatus, and an electronic device including the display apparatus. The display apparatus includes: a display panel including an opening area having an opening portion, a display area at least partially surrounding the opening area, and a middle area positioned between the opening area and the display area; a cover window disposed to cover a first surface of the display panel; a first resin structure disposed on a second surface of the display panel along a periphery of the display panel, the second surface including a side surface of the display panel and a surface of the display panel opposite to the first surface; and a second resin structure disposed inside the opening portion.

This application claims priority to Korean Patent Application No. 10-2024-0179691, filed on Dec. 5, 2024, and all the benefits accruing therefrom under 35 U.S.C. § 119, the content of which in its entirety is herein incorporated by reference.

### BACKGROUND

### 1. Field

One or more embodiments relate to a device and a method, and more particularly, to a display apparatus, a manufacturing apparatus of the display apparatus, a method of manufacturing the display apparatus, and an electronic device.

### 2. Description of the Related Art

Mobility-based electronic devices are widely used. In addition to small electronic devices such as mobile phones, tablet personal computers (PC) have been widely used in recent years as mobile electronic devices.

Such a mobile electronic device includes a display device that provides various functions, that is, providing visual information, such as an image or a video, to a user. Recently, the proportion of display apparatuses in electronic devices has increased, and structures that may be bent to a certain angle from a flat state have also been developed.

The above-mentioned background art is technical information that the inventor possesses for deriving the disclosure or obtains in the process of deriving the disclosure, and is not necessarily known technology disclosed to the general public prior to the filing of the disclosure.

### SUMMARY

A display apparatus includes a display panel. In this case, the display panel may be inserted into a housing, and impact to the edges of the display panel may be caused due to a contact between the display panel and the housing, resulting in damage to the display panel. In addition, when the display panel has an opening portion, the opening portion of the display panel may be damaged.

To solve various problems including the above problems, embodiments of the disclosure provide a display apparatus in which damage to a display panel accommodated inside a housing may be prevented, a manufacturing apparatus of the display apparatus, a method of manufacturing the display apparatus, and an electronic device.

However, these aspects are examples, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a display panel including an opening area having an opening portion, a display area at least partially surrounding the opening area, and a middle area positioned between the opening area and the display area, a cover window disposed to cover a first surface of the display panel, a first resin structure disposed on a second surface of the display panel along a periphery of the display panel, the second surface including a side surface of the display panel and a surface of the display panel opposite to the first surface, and a second resin structure disposed inside the opening portion.

In an embodiment, in a plan view, the second resin structure may be disposed inside an inner periphery of the first resin structure.

In an embodiment, in a plan view, the second resin structure may be disposed in a ring shape along an inner surface of the display panel, and the inner surface of the display panel may define the opening portion.

In an embodiment, the second resin structure may include a first portion disposed on an inner surface of the display panel, the inner surface defining the opening portion, and a second portion extending from the first portion to the outside of the opening area to cover the middle area.

In an embodiment, the first portion may be provided in a cylindrical shape, and the second portion may be provided in a ring shape.

In an embodiment, the second resin structure may include a different material from a material of the first resin structure.

In an embodiment, the display panel may further include an image generating layer for emitting light to display an image and an optical functional layer disposed on an upper portion of the image generating layer, and the second resin structure may be adhered to an inner surface of the optical functional layer, and the inner surface of the optical functional layer may define the opening portion.

In an embodiment, the optical functional layer may include a first protective layer, a second protective layer, and a polarizing layer between the first protective layer and the second protective layer, and the second resin structure may be adhered to an inner surface of the polarizing layer, and the inner surface of the polarizing layer may define the opening portion.

In an embodiment, the second resin structure may be adhered to the inner surface of the polarizing layer by hydrogen bonding.

In an embodiment, the second resin structure may include an acrylic material.

In an embodiment, an adhesive strength of the second resin structure may be 10 newtons per square centimeters (N/cm²) to 50 N/cm².

According to one or more embodiments, a manufacturing apparatus of a display apparatus includes a first jig, a second jig on which a display panel having an opening portion is mounted and disposed to face the first jig, a first mold disposed between the first jig and the second jig, selectively coupled to the first jig, and forming a first space outside an edge portion of the display panel together with the second jig so that a resin is injected into the first space, and a second mold forming a second space inside the opening portion so that a resin is injected into the second space.

In an embodiment, the second mold may include a shaft extending in a vertical direction, and a lid having a flat surface connected to an upper surface of the shaft and a side surface spaced apart from and surrounding an outer peripheral surface of the shaft.

In an embodiment, a length of the shaft in the vertical direction may be greater than a length of the side surface of the lid in the vertical direction.

In an embodiment, the second mold may be disposed inside an edge of the first mold formed into a closed loop in a plan view.

According to one or more embodiments, a method of manufacturing a display apparatus includes disposing, on a second jig spaced apart from a first jig, a display panel having an opening portion, forming a space in and outside the display panel by disposing the first jig and a mold on the display panel, supplying a photocurable resin into the space, and curing the photocurable resin by irradiating light into the space, wherein the mold includes a first mold surrounding an edge portion of the display panel to form a first space and a second mold forming a second space in the opening portion, and the space includes the first space and the second space.

In an embodiment, the second mold may include a shaft extending in a vertical direction, and a lid having a flat surface connected to an upper surface of the shaft and a side surface spaced apart from and surrounding an outer peripheral surface of the shaft.

In an embodiment, the shaft may be inserted into a center of the opening portion, and the lid may be disposed to cover a periphery of the opening portion.

In an embodiment, a photocurable resin supplied to the first space may be different from a photocurable resin supplied to the second space.

In an embodiment, an adhesive strength of a photocurable resin supplied to the second space may be 10 N/cm² to 50 N/cm².

According to one or more embodiments, an electronic device includes a display apparatus, and a housing accommodating the display apparatus, and the display apparatus includes a display panel including an opening area having an opening portion, a display area at least partially surrounding the opening area, and a middle area positioned between the opening area and the display area, a cover window disposed to cover a first surface of the display panel, a first resin structure disposed on a second surface of the display panel along a periphery of the display panel, the second surface including a side surface of the display panel and a surface of the display panel opposite to the first surface, and a second resin structure disposed inside the opening portion.

Other aspects, features, and advantages other than those described above will now become apparent from the following drawings, claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of an electronic device according to an embodiment;

FIG. 2 is a schematic cross-sectional view of the electronic device taken along line II-II′ of FIG. 1, according to an embodiment;

FIG. 3 is a schematic plan view of a display apparatus according to an embodiment;

FIG. 4 is a schematic rear view of the display apparatus according to an embodiment;

FIG. 5 is a cross-sectional view of the display apparatus taken along line V-V′ shown in FIG. 3;

FIG. 6 is a schematic cross-sectional view of the display apparatus taken along line VI-VI′ of FIG. 3, according to an embodiment;

FIG. 7 is an enlarged cross-sectional view of a region VII of FIG. 6, schematically illustrating the display apparatus according to an embodiment;

FIG. 8 is a schematic cross-sectional view of a display panel according to an embodiment;

FIGS. 9 and 10 are circuit diagrams each schematically showing a circuit of the display panel of FIG. 8;

FIG. 11 is a schematic perspective view of a manufacturing apparatus of a display apparatus according to an embodiment;

FIG. 12 is a schematic diagram of a manufacturing apparatus of a display apparatus, viewed in a direction A, according to an embodiment;

FIG. 13 is a cross-sectional view of the manufacturing apparatus of a display apparatus taken along line B-B′ of FIG. 12, according to an embodiment;

FIG. 14 is a cross-sectional view of the manufacturing apparatus of a display apparatus taken along line C-C′ of FIG. 12, according to an embodiment; and

FIG. 15 is a schematic perspective view of a second mold according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure will now be described more fully with reference to the accompanying drawings, in which embodiments of the disclosure are shown. Like reference numerals in the drawings denote like elements, and thus their description will not be repeated.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the disclosure, and are not intended to preclude the possibility that one or more other features or elements may exist or may be added.

It will be understood that when a layer, region, or element is referred to as being formed on another layer, region, or element, it can be directly or indirectly formed on the other layer, region, or element. That is, for example, intervening layers, regions, or elements may be present.

It will be understood that when a layer, region, or component is referred to as being connected to another layer, region, or component, it can be directly and/or indirectly connected to the other layer, region, or component. That is, for example, intervening layers, regions, or components may be present. In addition, it will be understood that when a layer, region, or component is referred to as being electrically connected to another layer, region, or component, it can be directly and/or indirectly electrically connected to the other layer, region, or component. That is, for example, intervening layers, regions, or components may be present.

Sizes of elements in the drawings may be exaggerated for convenience of explanation. In other words, since sizes and thicknesses of components in the drawings are arbitrarily illustrated for convenience of explanation, the following embodiments are not limited thereto.

In the following embodiments, “A and/or B” may include “A,” “B,” or “A and B.” In addition, “at least any one of A and B” or “at least one selected from A and B” may include “A,” “B,” or “A and B.”

In the following embodiments, it will be understood that when a wire is referred to as “extending in a first direction or a second direction”, it can not only extend in a linear shape, but also can extend in the first direction or the second direction in a zigzag or curved shape.

In the following embodiments, “in a plan view” means that an object part is viewed from above (i.e., z direction). Z direction is a thickness direction of a display panel 10. In the following embodiments, “in a cross-sectional view” means that an object part is vertically cut and viewed from the side (i.e., direction perpendicular to the z direction). In the following embodiments, a first component “overlapping” a second component means that the first component is positioned above or below the second component.

The x-axis, the y-axis, and the z-axis are not limited to three axes on the orthogonal coordinates system, and may be interpreted in a broad sense including the same. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

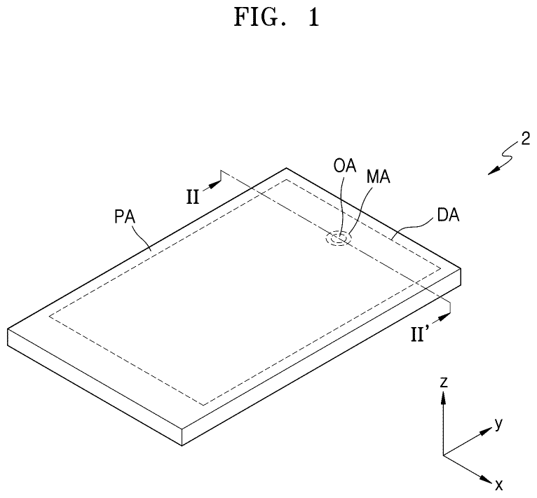

FIG. 1 is a schematic perspective view of an electronic device according to an embodiment.

Referring to FIG. 1, an electronic device 2 is an apparatus which displays a video or a still image. The electronic device 2 may be a portable electronic device, such as a mobile phone, a smartphone, a tablet personal computer (PC), a mobile communication terminal, an electronic notebook, an electronic book, a portable multimedia player (PMP), a navigation device, an Ultra Mobile PC (UMPC), or the like, and may also be used as a display screen of various products, such as a television, a laptop computer, a monitor, an advertisement board, an Internet of things (IoT) device, or the like. In addition, the electronic device 2 according to an embodiment may be applied to a wearable device, such as a smart watch, a watch phone, a glasses-type display, and a head mounted display (HMD). In addition, the electronic device 2 according to an embodiment may be used as a dashboard of a vehicle, a center fascia of a vehicle or a center information display (CID) disposed on a dashboard, a room mirror display replacing a side mirror of a vehicle, and a display screen disposed on the back of a front seat as entertainment for a passenger in a back seat of a vehicle. For convenience of description, in FIG. 1, the electronic device 2 according to an embodiment is shown as a smartphone.

The electronic device 2 may have a rectangular shape in a plan view. For example, the electronic device 2 may have a rectangular planar shape having a short side in an x direction and a long side in a y direction, as shown in FIG. 1. A corner where the short side in the x direction and the long side in the y direction meet may be rounded to have a certain curvature or may be formed at a right angle. The planar shape of the electronic device 2 is not limited to a rectangular shape, and may be formed in other polygonal, elliptical, or irregular shapes.

The electronic device 2 may include an opening area OA (or a first area) and a display area DA (or a second area) at least surrounding the opening area OA. The electronic device 2 may include a middle area MA (or a third area) positioned between the opening area OA and the display area DA, and a peripheral area PA (or a fourth area) outside the display area DA, for example, surrounding the display area DA. In an embodiment, the middle area MA may have a closed-loop shape that entirely surrounds the opening area OA in a plan view.

The opening area OA may be positioned inside the display area DA. In an embodiment, the opening area OA may be disposed at the center on an upper side of the display area DA, as shown in FIG. 1. Alternatively, the opening area OA may be variously disposed, for example, on an upper left side of the display area DA or an upper right side of the display area DA. Although FIG. 1 illustrates that one opening area OA is disposed, in another embodiment, a plurality of opening areas OA may be provided.

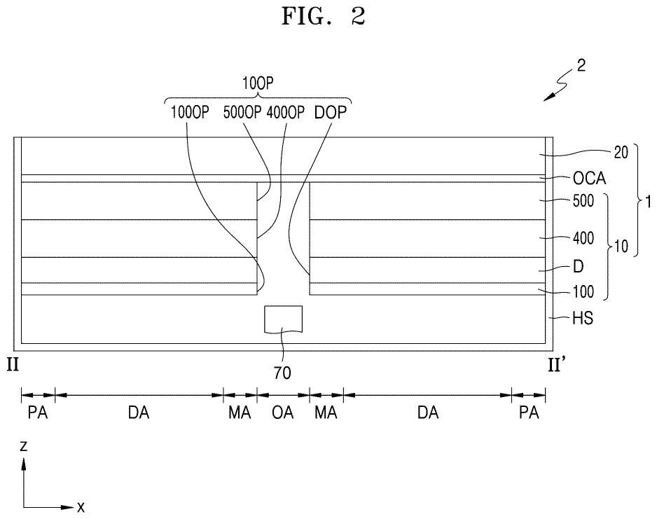

FIG. 2 is a schematic cross-sectional view of the electronic device taken along line II-II′ of FIG. 1, according to an embodiment.

Referring to FIG. 2, the electronic device 2 may include a display apparatus 1 and a housing HS. The display apparatus 1 may include a display panel 10, a component 70 disposed in an opening area OA of the display panel 10, and a cover window 20. The display panel 10, the cover window 20, and the component 70 may be accommodated in the housing HS.

In an embodiment, the display panel 10 may include a substrate 100, a display layer D, a touch sensor layer 400, and an optical functional layer 500.

The display layer D may include display elements (or light-emitting elements) that emit light to display an image. A display element may include a light-emitting diode, for example, an organic light-emitting diode including an organic emission layer. In another embodiment, the light-emitting diode may be an inorganic light-emitting diode including an inorganic material. The inorganic light-emitting diode may include a PN junction diode including materials based on inorganic semiconductors. When a voltage is applied to the PN junction diode in a forward direction, holes and electrons may be injected, and energy generated by recombination of the holes and electrons may be converted into light energy to emit a certain color of light. The above-described inorganic light-emitting diode may have a width of several to several hundred micrometers, or several to several hundred nanometers. In some embodiments, the display layer D may include quantum dots light-emitting diode. For example, an emission layer of the display layer D may include an organic material, an inorganic material, quantum dots, an organic material and quantum dots, or an inorganic material and quantum dots. The display layer D may be referred to as an “image generating layer”.

The touch sensor layer 400 may obtain coordinate information according to an external input, for example, a touch event. The touch sensor layer 400 may include a sensing electrode (or a touch electrode) and a trace line connected to the sensing electrode. The touch sensor layer 400 may be disposed on the display layer D. The touch sensor layer 400 may sense an external input in a mutual-cap method and/or a self-cap method.

The touch sensor layer 400 may be directly formed on the display layer D, or may be separately formed and then coupled to the display layer D through an adhesive layer such as an optical clear adhesive. For example, the touch sensor layer 400 may be continuously formed after a process of forming the display layer D, and in this case, the adhesive layer may not be between the touch sensor layer 400 and the display layer D. FIG. 2 illustrates that the touch sensor layer 400 is between the display layer D and the optical functional layer 500, but in another embodiment, the touch sensor layer 400 may be disposed above the optical functional layer 500.

The optical functional layer 500 may reduce the reflectance of light (for example, external light) incident from the outside toward the electronic device 2, and may, at the same time, control a traveling direction of light emitted by the display layer D.

To improve the transmittance of the opening area OA, the display panel 10 may include an opening portion 10OP penetrating some of the layers forming the display panel 10. The opening portion 10OP may include first to fourth openings 100OP, DOP, 400OP, and 500OP penetrating the substrate 100, the display layer D, the touch sensor layer 400, and the optical functional layer 500, respectively. The first opening 100OP of the substrate 100, the second opening DOP of the display layer D, the third opening 400OP of the touch sensor layer 400, and the fourth opening 500OP of the optical functional layer 500 may overlap each other to form the opening portion 10OP of the display panel 10.

The cover window 20 may be disposed on the optical functional layer 500. The cover window 20 may be coupled to the optical functional layer 500 through an adhesive layer, such as an optical clear adhesive (OCA), between the cover window 20 and the optical functional layer 500. The cover window 20 may cover the first opening 100OP of the substrate 100, the second opening DOP of the display layer D, the third opening 400OP of the touch sensor layer 400, and the fourth opening 500OP of the optical functional layer 500.

The cover window 20 may include a glass material or a plastic material. The glass material may include ultra-thin glass. The plastic material may include polyethersulfone, polyacrylate, polyetherimide, polyethylene naphthalate, PET polyphenylene sulfide, polyarylate, PI, polycarbonate, cellulose acetate propionate, or the like.

The opening area OA may be a kind of component area (e.g., a sensor area, a camera area, a speaker area, or the like) in which the component 70 configured to add various functions to the electronic device 2 is positioned.

The component 70 may include an electronic element. For example, the component 70 may be an electronic element using light or sound. For example, the electronic element may include a sensor using light, such as an infrared sensor, a camera capturing an image by receiving light, a sensor outputting and sensing light or sound to measure a distance or recognize a fingerprint or the like, a small lamp outputting light, a speaker outputting sound, or the like. An electronic element using light may use light of various wavelengths such as visible light, infrared light, ultraviolet light, or the like. The opening area OA corresponds to an area through which light and/or sound output from the component 70 to the outside or travelling from the outside toward the electronic element may be transmitted.

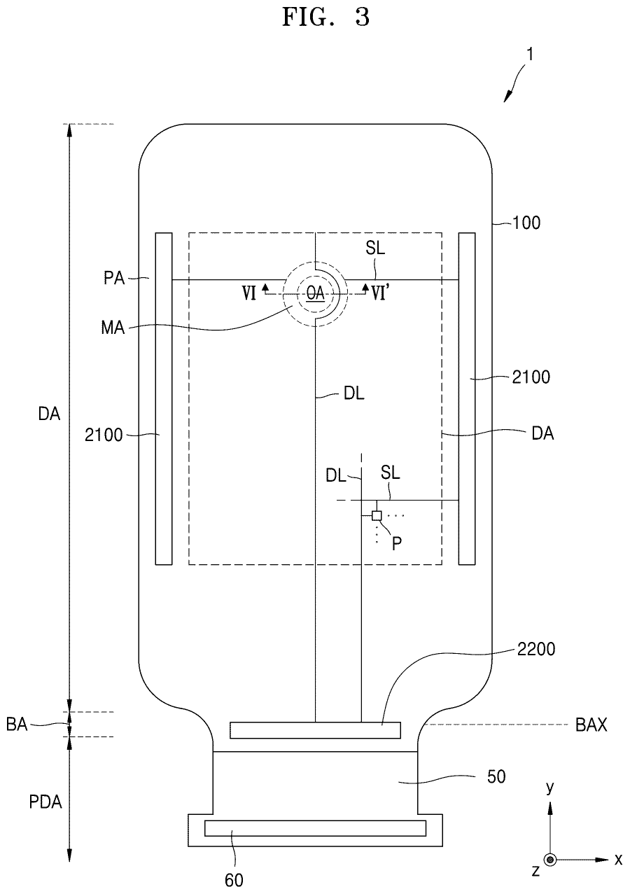

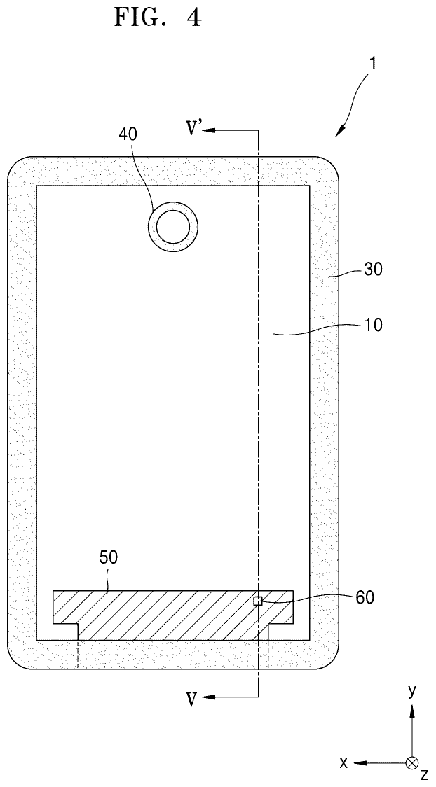

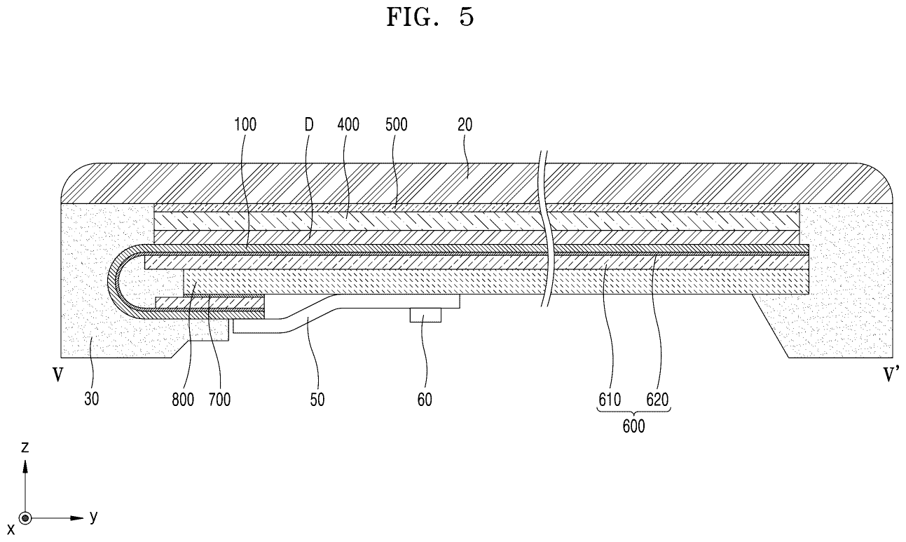

FIG. 3 is a schematic plan view of a display apparatus according to an embodiment. FIG. 4 is a schematic rear view of the display apparatus according to an embodiment. FIG. 5 is a cross-sectional view of the display apparatus taken along line V-V′ shown in FIG. 3.

Referring to FIGS. 3 to 5, a display apparatus 1 may include a plurality of sub-pixels P disposed in the display area DA, and the display apparatus 1 may display an image by using light emitted by each of the plurality of sub-pixels P. Each sub-pixel P may emit red, green, or blue light by using a light-emitting diode. The light-emitting diode of each sub-pixel P may be connected to a scan line SL and a data line DL.

A scan driver 2100 providing a scan signal to each sub-pixel P, a data driver 2200 providing a data signal to each sub-pixel P, and a first main power line (not shown) and a second main power line (not shown), which are configured to provide a first power voltage and a second power voltage, may be disposed in the peripheral area PA. The scan driver 2100 may be disposed on each of both sides of the display area DA with the display area DA therebetween. In this case, the sub-pixel P disposed on the left side with respect to the opening area OA may be connected to the scan driver 2100 on the left side, and the sub-pixel P disposed on the right side with respect to the opening area OA may be connected to the scan driver 2100 on the right side.

The middle area MA may surround the opening area OA. The middle area MA is an area in which a display element, such as a light-emitting diode emitting light, is not disposed, and signal lines providing signals to the sub-pixels P provided around the opening area OA may pass by the middle area MA. For example, data lines DL and/or scan lines SL may cross the display area DA, and some of the data lines DL and/or scan lines SL may bypass the middle area MA along an edge of the opening portion 10OP of the display panel 10 formed in the opening area OA. In an embodiment, FIG. 3 illustrates that the data lines DL cross the display area DA in a y direction, and some of the data lines DL bypass the middle area MA to partially surround the opening area OA. The scan lines SL cross the display area DA in an x direction, and may be spaced apart from each other with the opening area OA therebetween.

FIG. 3 illustrates that the data driver 2200 is disposed adjacent to one side of the substrate 100, but in another embodiment, the data driver 2200 may be disposed on a printed circuit board electrically connected to a pad disposed on one side of the display panel 10. The printed circuit board may have flexibility, and a portion of the printed circuit board may be bent to be positioned under a rear surface of the substrate 100.

The display panel 10 may be a flexible display panel that may be easily bent, folded, or rolled due to flexibility. For example, the display panel 10 may be a foldable display panel that may be folded and unfolded, a curved display panel with a curved display surface, a bended display panel having an area, other than a display surface, that is curved, a rollable display panel that may be rolled or unrolled, and a stretchable display panel that may be stretched.

The display panel 10 as described above may include the display area DA that realizes an image and the peripheral area PA disposed to surround the display area DA. A separate driving circuit, a pad, or the like may be disposed in the peripheral area PA.

In particular, the peripheral area PA may include a bending area BA that is bent around a bending axis BAX and a pad area PDA connected to the bending area BA and in which a display circuit board 50 is disposed. In the display panel 10, a portion of the substrate 100 may be bent based on the bending axis BAX, which is virtual, disposed in the bending area BA. That is, as the display panel 10 is bent in the bending area BA, the display area DA and the pad area PDA may be disposed to face each other.

The display apparatus 1 may include the display panel 10, the cover window 20 covering the display panel 10, a first resin structure 30 disposed to surround side surfaces of the display panel 10, and a second resin structure 40 disposed to fill at least a portion of the opening portion 10OP of the display panel 10.

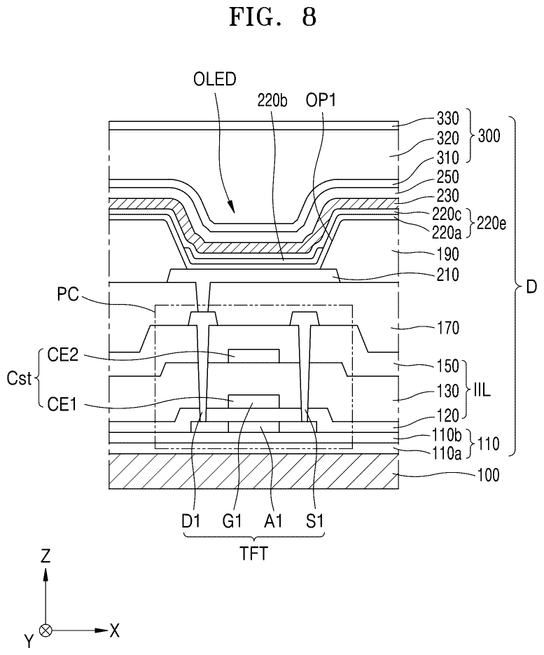

The display panel 10 may include the substrate 100, a pixel circuit PC(refer to FIG. 8) disposed on the substrate 100, the display layer D including an emission layer, the touch sensor layer 400 on the display layer D, and the optical functional layer 500 on the touch sensor layer 400.

The display panel 10 may be disposed on a lower portion of the cover window 20. The display apparatus 1 may include a protective film 600 and an adhesive member 700, which are disposed on a lower portion of the substrate 100. In this case, the protective film 600 may include a protective film base 610 and an adhesive layer 620. In this case, the protective film base 610 may include polyethylene terephthalate (PET) or polyimide (PI). Also, the adhesive layer 620 may include various adhesive materials. In this case, the adhesive layer 620 may be disposed on a front surface of the substrate 100, and the protective film base 610 may be partially removed after being disposed on the adhesive layer 620 to form an opening portion. As another embodiment, although not illustrated in the drawing, a portion of the protective film base 610 and a portion of the adhesive layer 620 may be removed to form an opening portion. In this case, both the protective film base 610 and the adhesive layer 620 may not be present in the opening portion.

In addition, the display apparatus 1 may include a cushion layer 800 between protective film bases 610. In this case, the cushion layer 800 may be disposed in an area where the display area DA and the pad area PDA face each other. That is, the cushion layer 800 may be disposed to contact a portion of the protective film base 610 in the display area DA and a portion of the protective film base 610 in the pad area PDA. The cushion layer 800 may be disposed in a space where the display area DA and the pad area PDA are spaced apart from each other after the substrate 100 or the like is bent to support the display panel 10 and absorb impact. The cushion layer 800 may include an elastic material. In this case, a display apparatus is not limited thereto, and the cushion layer 800 may be attached to the protective film base 610 before being bent.

The display panel 10 may be connected to the display circuit board 50 through an anisotropic conductive film. A touch sensor driving unit 60 may be disposed on the display circuit board 50. As an embodiment, the touch sensor driving unit 60 may also be directly disposed on the substrate 100 of the display panel 10. Hereinafter, for convenience of explanation, a case in which the touch sensor driving unit 60 is disposed on the display circuit board 50 is mainly described in detail.

The touch sensor layer 400 may be formed in a form of a panel or film. Alternatively, the touch sensor layer 400 may be integrally formed with the display layer D. For example, when the touch sensor layer 400 is formed in a form of a film, the touch sensor layer 400 may be integrally formed with a thin-film encapsulation layer of the display panel 10.

As another embodiment, the touch sensor layer 400 may also be disposed on the display layer D with an electrode in a form of a pattern. In this case, lines may be disposed on a thin-film encapsulation layer 300 (refer to FIG. 8) to intersect each other, and a change in electrostatic capacitance that varies according to a user's touch may be measured at a point of intersection of the lines. The touch sensor layer 400 as described above may be connected to the display circuit board 50.

The touch sensor driving unit 60 may apply touch driving signals to the touch sensor layer 400, sense first sensing signals sensed from the touch sensor layer 400, and analyze the first sensing signals to calculate a touch position of the user. Also, the touch sensor driving unit 60 may apply touch driving signals to a sensing unit, sense second sensing signals sensed from the sensing unit (not shown), and analyze the second sensing signals to calculate a touch position of a signal input unit (not shown).

In an embodiment, the optical functional layer 500 may be disposed on the touch sensor layer 400. The optical functional layer 500 may reduce the reflectance of light (external light) incident from the outside toward the display apparatus 1.

The display circuit board 50 may be attached to one side of the display panel 10. In particular, the display circuit board 50 may be attached to pads provided on one side of the display panel 10 by using an anisotropic conductive film. The display circuit board 50 may be connected to a main circuit board through a display connection unit (not shown).

The display panel 10 may include the display area DA having a width in a first direction (for example, an x direction) and a length in a second direction (for example, a y direction) crossing the first direction, and a pad area PDA. In this case, the display area DA and the pad area PDA may be disposed in parallel to each other in the second direction, and the bending area BA may be disposed between the display area DA and the pad area PDA to connect the display area DA and the pad area PDA to each other. In addition, the bending area BA may be bent so that the display area DA and the pad area PDA face each other. In this case, it will be understood that the bending area BA is connected to any one of edges of the display area DA.

The cover window 20 may be disposed to cover the display panel 10. In an embodiment, the cover window 20 may include a transparent material. In an embodiment, the cover window 20 may include a glass material or a plastic material. The glass material may include ultra-thin glass. The plastic material may include polyethersulfone, polyacrylate, polyetherimide, polyethylene naphthalate, polyethylene terephthalate, polyphenylene sulfide, polyarylate, PI, polycarbonate, cellulose acetate propionate, or the like.

The first resin structure 30 may be disposed to surround side portions of the display panel 10. In an embodiment, the display panel 10 may include a first surface for displaying images and a second surface including a side surface and a surface opposite to the first surface. The cover window 20 may be disposed on the first surface of the display panel 10, and the first resin structure 30 may be disposed on the second surface of the display panel 10. In this case, the first resin structure 30 may be disposed along the periphery of the display panel 10 and may extend to surround the side portions of the display panel 10. Accordingly, the first resin structure 30 may be disposed to cover a portion of the second surface of the display panel 10, for example, the periphery thereof, and extend outward to cover the periphery of the cover window 20. In an embodiment, the first resin structure 30 may be disposed in a closed loop along the periphery of the display panel 10.

In an embodiment, the first resin structure 30 may include resin. As to be described below, the first resin structure 30 may be formed by injecting resin into a mold and curing the injected resin.

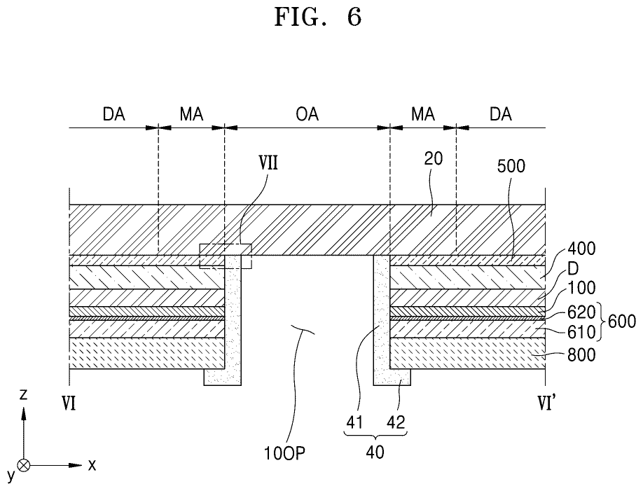

FIG. 6 is a schematic cross-sectional view of the display apparatus 1( [symbol] ) taken along line VI-VI′ of FIG. 3, according to an embodiment.

In addition, referring to FIG. 6, in an embodiment, the display apparatus 1 may include the second resin structure 40. The second resin structure 40 may be disposed within the opening area OA as described above, that is, the opening portion 10OP. That is, in an embodiment, the first resin structure 30 may be disposed along the periphery of the display panel 10, and in a plan view, the second resin structure 40 may be disposed inside the inner periphery of the first resin structure 30.

In an embodiment, the second resin structure 40 may be disposed in a ring shape along the inner surface of the display panel 10, which defines the opening portion 10OP. The second resin structure 40 may be in contact with and attached to the inner surface of the display panel 10, which defines the opening portion 10OP.

In addition, in an embodiment, the second resin structure 40 may include a first portion 41 and a second portion 42. The first portion 41 may be a portion disposed on the inner surface of the display panel 10, which defines the opening portion 10OP. In an embodiment, the first portion 41 may be provided in a cylindrical shape, that is, a pipe shape. The second portion 42 may be a portion protruding radially outward from an end of the first portion 41. The second portion 42 may be disposed to cover the second surface of the display panel 10, and may be disposed to extend toward the outside of the opening area OA from the first portion 41 to cover at least a portion of the middle area MA. In an embodiment, the second portion 42 may be provided in a ring shape. The shape of the second resin structure 40 may be due to a process of manufacturing the second resin structure 40.

The second resin structure 40 may be in contact with and attached to the inner surface of the display panel 10, which defines the opening portion 10OP, to prevent damage to the display panel 10 in the opening area OA. In particular, when the first resin structure 30 is disposed on the periphery of the display panel 10 and the second resin structure 40 is not disposed, the display panel 10, particularly the optical functional layer 500, may be fixed by the first resin structure 30, causing limitations to shrinkage and expansion due to temperature changes at the periphery of the display panel 10. On the contrary, because there is no resin structure in the opening portion 10OP of the display panel 10, the display panel 10, particularly the optical functional layer 500, may experience concentrated shrinkage and expansion in the opening area OA, and thus the optical functional layer 500 may be damaged. According to embodiments of the disclosure, the display panel 10, particularly the optical functional layer 500, may have the same degree of shrinkage and expansion in the opening area OA and prevent damage through the second resin structure 40 that is in contact with and attached to the opening portion 10OP of the display panel 10.

In addition, the second resin structure 40 may be more firmly supported on the display panel 10 through the second portion 42 and may be more firmly attached to the inner side of the opening portion 10OP of the display panel 10 without being removed.

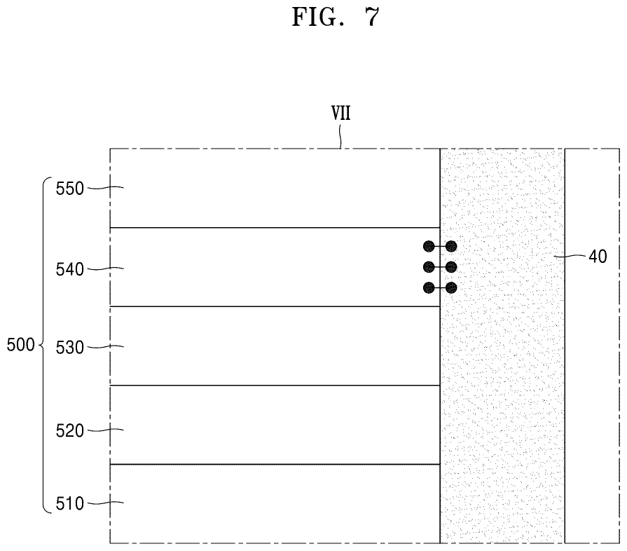

FIG. 7 is an enlarged cross-sectional view of a region VII of FIG. 6, schematically illustrating the display apparatus according to an embodiment.

Referring to FIG. 7, the optical functional layer 500 may include a phase retardation layer (PRL) 510, an adhesive layer 520, a first protective layer 530, a polarizing layer 540, and a second protective layer 550.

The polarizing layer 540 may polarize light incident from a light source (not shown) into light in the same direction as a polarization axis. In some embodiments, the polarizing layer 540 may be formed by including a polarizer and/or dichroic dye in a polyvinyl alcohol (PVA) film. The dichroic dye may be an iodine molecule and/or a dye molecule.

In some embodiments, the polarizing layer 540 may be formed by stretching a PVA film in one direction and immersing the PVA film in a solution of iodine and/or dichroic dye. In this case, the iodine molecules and/or dichroic dye molecules are arranged parallel to a stretching direction. Because the iodine molecules and the dye molecules exhibit dichroism, the iodine molecules and the dye molecules may absorb light that vibrates in the stretching direction and transmit light that vibrates in a direction perpendicular to the stretching direction.

The PRL 510 may be disposed on one side, for example, the lower portion, of the polarizing layer 540 to delay phase of entering light reflected by a metal layer inside the display panel 10. For example, the PRL 510 may delay the phase of reflected light by λ/4 to circularly polarize the reflected light. Accordingly, the reflectance of light may be reduced. In some embodiments, the PRL 510 may have a wavelength dependency, and a phase delay value may decrease toward a shorter wavelength.

The first protective layer 530 and the second protective layer 550 may support the optical functional layer 500, particularly the polarizing layer 540 and the PRL 510, to serve as a protective layer supplementing the mechanical strength of the polarizing layer 540 and the PRL 510. The first protective layer 530 may be disposed between the polarizing layer 540 and the PRL 510. The second protective layer 550 may be disposed on an upper portion of the polarizing layer 540. In this case, the first protective layer 530 may be attached to the PRL 510 by the adhesive layer 520. It is described above that the first protective layer 530 is disposed between the polarizing layer 540 and the PRL 510, but in another embodiment, it will be understood that the first protective layer 530 may be disposed on a lower portion of the PRL 510.

In an embodiment, the first protective layer 530 may include a tri-acetyl cellulose (TAC), and the second protective layer 550 may include a cyclic olefin polymer (COP). Alternatively, in another embodiment, each of the first protective layer 530 and the second protective layer 550 may include at least one of TAC, COP, and polymethyl methacrylate (PMMA).

In addition, although not illustrated in the drawing, in an embodiment, a hard coating layer may be disposed on the second protective layer 550. The hard coating layer may be a composition for protecting the composition of the optical functional layer 500 from external impact. The hard coating layer may have a scratch-resistant function.

As described above, the second resin structure 40 may be in contact with and attached to the inner surface of the display panel 10 along the inner surface of the display panel 10, which defines the opening portion 10OP. In this case, the second resin structure 40 may be in contact with and attached to the optical functional layer 500. For example, the second resin structure 40 may be in contact with and attached to the opening portion 10OP along the opening portion 10OP, particularly the inner surface of the optical functional layer 500, which defines the fourth opening 500OP. The second resin structure 40 may include a resin having high adhesive strength to be strongly adhered to the inner surface of the polarizing layer 540 of the optical functional layer 500.

In an embodiment, the second resin structure 40 may include a different material from that of the first resin structure 30. For example, the first resin structure 30 may include a silicon material, and the second resin structure 40 may include an acrylic-based material. The second resin structure 40 may have an improved adhesive strength to the polarizing layer 540 through hydrogen bonding or covalent bonding. To this end, in an embodiment, the polarizing layer 540 may be preceded by surface treatment such as plasma or ultraviolet ozone treatment. In an embodiment, the adhesive strength of the second resin structure 40 may be 10 N/cm² to 50 N/cm² . When the adhesive strength of the second resin structure 40 is less than 10 N/cm² , the second resin structure 40 may fall off due to weak adhesion to the inner surface of the optical functional layer 500, causing the occurrence of a gap. Such a gap may cause cracks in the optical functional layer 500. When the adhesive strength of the second resin structure 40 is greater than 50 N/cm² , it may be difficult to control the application thereof when using the second resin structure 40 in a process due to high adhesive strength.

In addition, in an embodiment, the second resin structure 40 may include a black material. For example, the second resin structure 40 may include a black dye or the like. Accordingly, the second resin structure 40 may prevent cracks in the optical functional layer 500 while simultaneously preventing light leakage.

FIG. 8 is a schematic cross-sectional view of a display panel according to an embodiment.

Referring to FIG. 8, the display panel 10 may include the substrate 100, the display layer D, the touch sensor layer 400, and the optical functional layer 500 (refer to FIG. 5). Hereinafter, the substrate 100 and the display layer D are mainly described. The display layer D may be provided by stacking a buffer layer 110, a circuit layer (not shown), a display element layer (not shown), and a thin-film encapsulation layer 300.

As described above, the substrate 100 may include an insulating material, such as glass, quartz, a polymer resin, or the like. The substrate 100 may be a flexible substrate capable of bending, folding, rolling, or the like.

The buffer layer 110 may be positioned on the substrate 100 to reduce or block penetration of a foreign material, moisture, or external air from below the substrate 100 and provide a flat surface onto the substrate 100. The buffer layer 110 may include an inorganic material such as an oxide or a nitride, an organic material, or an organic and inorganic composite, and may include a single-layered structure or a multi-layered structure, each including an inorganic material and an organic material. A barrier layer (not shown) blocking penetration of external air may be further included between the substrate 100 and the buffer layer 110. In some embodiments, the buffer layer 110 may include silicon oxide (SiO₂) or silicon nitride (SiNₓ). The buffer layer 110 may be provided by stacking a first buffer layer 110a and a second buffer layer 110b.

The circuit layer may be disposed on the buffer layer 110 and include a pixel circuit PC, a first gate insulating layer 120, a second gate insulating layer 130, an interlayer insulating layer 150, and a planarization layer 170. The pixel circuit PC may include a thin-film transistor TFT and the storage capacitor Cst.

The thin-film transistor TFT may be disposed on the buffer layer 110. The thin-film transistor TFT may include a first semiconductor layer A1, a first gate electrode G1, a first source electrode S1, and a first drain electrode D1. The thin-film transistor TFT may be connected to an organic light-emitting diode OLED to drive the organic light-emitting diode OLED.

The first semiconductor layer A1 may be disposed on the buffer layer 110 and include polysilicon. As another embodiment, the first semiconductor layer A1 may include amorphous silicon. As another embodiment, the first semiconductor layer A1 may include an oxide of at least one material selected from a group consisting of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The first semiconductor layer A1 may include a channel area, a source area, and a drain area, wherein the source area and the drain area are doped with impurities.

The first gate insulating layer 120 may be provided to cover the first semiconductor layer A1. The first gate insulating layer 120 may include an inorganic insulating material, such as silicon oxide (SiO₂), silicon nitride (SiNₓ), silicon oxynitride (SiON), aluminum oxide (Al₂O₃), titanium oxide (TiO₂), tantalum pentoxide (Ta₂O₅), hafnium oxide (HfO₂), or zinc peroxide (ZnOₓ), or the like. The first gate insulating layer 120 may include a single layer or a multi-layer, each including the inorganic insulating material stated above.

The first gate electrode G1 is disposed on the first gate insulating layer 120 to overlap the first semiconductor layer A1. The first gate electrode G1 may include molybdenum (Mo), aluminum (Al), copper (Cu), titanium (Ti), or the like, and may include a single layer or a multi-layer. For example, the first gate electrode G1 may have a single Mo layer.

The second gate insulating layer 130 may be provided to cover the first gate electrode G1. The second gate insulating layer 130 may include an inorganic insulating material, such as silicon oxide (SiO₂), silicon nitride (SiNₓ), silicon oxynitride (SiON), aluminum oxide (Al₂O₃), titanium oxide (TiO₂), tantalum pentoxide (Ta₂O₅), hafnium oxide (HfO₂), or zinc peroxide (ZnOₓ), or the like. The second gate insulating layer 130 may include a single layer or a multi-layer, each including the inorganic insulating material stated above.

A first upper electrode CE2 of the storage capacitor Cst may be disposed on the second gate insulating layer 130.

In the display area DA, the first upper electrode CE2 may overlap the first gate electrode G1 disposed below the first upper electrode CE2. The first gate electrode G1 and the first upper electrode CE2, which overlap each other with the second gate insulating layer 130 therebetween, may form the storage capacitor Cst. The first gate electrode G1 may be a first lower electrode CE1 of the storage capacitor Cst.

The first upper electrode CE2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may include a single layer or a multi-layer, each including the materials stated above.

The interlayer insulating layer 150 may be formed to cover the first upper electrode CE2. The interlayer insulating layer 150 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ), or the like. The interlayer insulating layer 150 may include a single layer or a multi-layer, each including the inorganic insulating material described above.

The first source electrode S1 and the first drain electrode D1 are disposed on the interlayer insulating layer 150. The first source electrode S1 and the first drain electrode D1 may each include a conductive material including Mo, Al, Cu, Ti, or the like, and may each include a multi-layer or a single layer, each including the above material. For example, the first source electrode S1 and the first drain electrode D1 may each have a multi-layered structure of Ti/Al/Ti.

The planarization layer 170 may be disposed to cover the first source electrode S1 and the first drain electrode D1. The planarization layer 170 may have a flat surface such that a pixel electrode 210 disposed on the planarization layer 170 may be formed flat.

The planarization layer 170 may include an organic material or an inorganic material, and may have a single-layered structure or a multi-layered structure. The planarization layer 170 may include a general-purpose polymer, such as benzocyclobutene (BCB), PI, hexamethyldisiloxane (HMDSO), PMMA, or polystyrene, a polymer derivative containing a phenol group, an acrylic polymer, an imide polymer, an aryl ether polymer, an amide polymer, a fluorine polymer, a p-xylene polymer, or a vinyl alcohol polymer, or the like. The planarization layer 170 may include an inorganic insulating material, such as silicon oxide (SiO₂), silicon nitride (SiNₓ), silicon oxynitride (SiON), aluminum oxide (Al₂O₃), titanium oxide (TiO₂), tantalum pentoxide (Ta₂O₅), hafnium oxide (HfO₂), or zinc peroxide (ZnOₓ), or the like. When the planarization layer 170 is formed, a layer may be formed and then chemical mechanical polishing may be performed on an upper surface of the layer to provide a flat upper surface.

The planarization layer 170 may have a via hole exposing any one of the first source electrode S1 and the first drain electrode D1 of the thin-film transistor TFT, and the pixel electrode 210 may be electrically connected to the thin-film transistor TFT by contacting the first source electrode S1 or the first drain electrode D1 through the via hole.

The pixel electrode 210 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). The pixel electrode 210 may include a reflective film including Ag, Mg, Al, Pt, Pd, Au, Ni, Nd, Ir, Cr, or a compound thereof. For example, the pixel electrode 210 may have a structure having films including ITO, IZO, ZnO, or In₂O₃ above/below the above-stated reflective film. In this case, the pixel electrode 210 may have a stacked structure of ITO/Ag/ITO.

A pixel defining layer 190 may cover an edge of the pixel electrode 210 on the planarization layer 170, and may have a pixel opening OP1 exposing the central portion of the pixel electrode 210. The size and shape of an emission area of the organic light-emitting diode OLED, that is, a sub-pixel P, are defined by the pixel opening OP1.

The pixel defining layer 190 may prevent an arc or the like from being generated at an edge of the pixel electrode 210 by increasing a distance between the edge of the pixel electrode 210 and an opposite electrode 230 above the pixel electrode 210. The pixel defining layer 190 may be formed of an organic insulating material such as PI, polyamide, acrylic resin, BCB, HMDSO, and phenol resin in a spin coating method or the like.

Emission layers 220b formed to respectively correspond to pixel electrodes 210 may be disposed inside the pixel opening OP1 of the pixel defining layer 190. An emission layer 220b may include a polymer material or a low-molecular-weight material, and may emit red, green, blue, or white light.

An organic functional layer 220e may be disposed on and/or below the emission layer 220b. The organic functional layer 220e may include a first functional layer 220a and/or a second functional layer 220c. The first functional layer 220a or the second functional layer 220c may be omitted.

The first functional layer 220a may be disposed below the emission layer 220b. The first functional layer 220a may be a single layer or a multi-layer, each including an organic material. The first functional layer 220a may be a hole transport layer (HTL) having a single-layered structure. Alternatively, the first functional layer 220a may include a hole injection layer (HIL) and an HTL. The first functional layer 220a may be integrally formed to correspond to organic light-emitting diodes OLED included in the display area DA and the middle area MA.

The second functional layer 220c may be disposed on the emission layer 220b. The second functional layer 220c may be a single layer or a multi-layer, each including an organic material. The second functional layer 220c may include an electron transport layer (ETL) and/or an electron injection layer (EIL). The second functional layer 220c may be integrally formed to correspond to organic light-emitting diodes OLED included in the display area DA.

The opposite electrode 230 is disposed on the second functional layer 220c. The opposite electrode 230 may include a conductive material having a low work function. For example, the opposite electrode 230 may include a (semi)transparent layer, the (semi)transparent layer including Ag, Mg, Al, Pt, Pd, Au, Ni, Nd, Ir, Cr, lithium (Li), Ca, alloys thereof, or the like. Alternatively, the opposite electrode 230 may further include a layer, such as ITO, IZO, ZnO, or In₂O₃, above the (semi)transparent layer including the materials stated above. The opposite electrode 230 may be integrally formed to correspond to the organic light-emitting diodes OLED included in the display area DA.

Layers from the pixel electrode 210 to the opposite electrode 230, which are formed in the display area DA, may form the organic light-emitting diode OLED.

An upper layer 250 including an organic material may be formed on the opposite electrode 230. The upper layer 250 may be a layer provided to increase light extraction efficiency while protecting the opposite electrode 230. The upper layer 250 may include an organic material having a higher refractive index than that of the opposite electrode 230. Alternatively, the upper layer 250 may be provided by stacking layers having different refractive indices from each other. For example, the upper layer 250 may be provided by stacking a high-refractive index layer/low-refractive index layer/high-refractive index layer. In this case, the refractive index of the high-refractive index layer may be 1.7 or more, and the refractive index of the low-refractive layer may be 1.3 or less.

The upper layer 250 may further include lithium fluoride (LiF). Alternatively, the upper layer 250 may further include an inorganic insulating material, such as silicon oxide (SiO₂) and silicon nitride (SiNₓ). The upper layer 250 may also be omitted when necessary. However, hereinafter, for convenience of explanation, a case in which the upper layer 250 is disposed on the opposite electrode 230 is mainly described in detail.

The thin-film encapsulation layer 300 may be disposed to directly contact the upper layer 250. In this case, the thin-film encapsulation layer 300 may cover a portion of the display area DA and the peripheral area PA to prevent penetration of external moisture and oxygen. The thin-film encapsulation layer 300 may include at least one organic encapsulation layer and at least one inorganic encapsulation layer. Hereinafter, for convenience of explanation, a case in which the thin-film encapsulation layer 300 includes a first inorganic encapsulation layer 310, an organic encapsulation layer 320, and a second inorganic encapsulation layer 330, which are sequentially stacked on an upper surface of the upper layer 250, is mainly described in detail.

In this case, the first inorganic encapsulation layer 310 may cover the opposite electrode 230, and may include silicon oxide, silicon nitride, and/or silicon oxynitride, or the like. Because the first inorganic encapsulation layer 310 is formed along an underlying structure, an upper surface of the first inorganic encapsulation layer 310 may not be flat. The organic encapsulation layer 320 covers the first inorganic encapsulation layer 310, and unlike the first inorganic encapsulation layer 310, an upper surface of the organic encapsulation layer 320 may be formed substantially flat. In particular, the organic encapsulation layer 320 may have a substantially flat upper surface in a portion corresponding to the display area DA. The organic encapsulation layer 320 may include one or more materials selected from a group consisting of PET, polyethylene naphthalate, polycarbonate, PI, polyethylene sulfonate, polyoxymethylene, polyarylate, and HMDSO. The second inorganic encapsulation layer 330 may cover the organic encapsulation layer 320, and may include silicon oxide, silicon nitride, and/or silicon oxynitride, or the like.

A touch sensor layer and an optical functional layer may be disposed on the thin-film encapsulation layer 300.

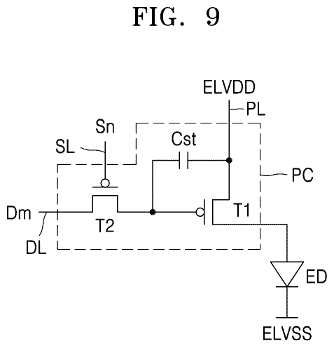

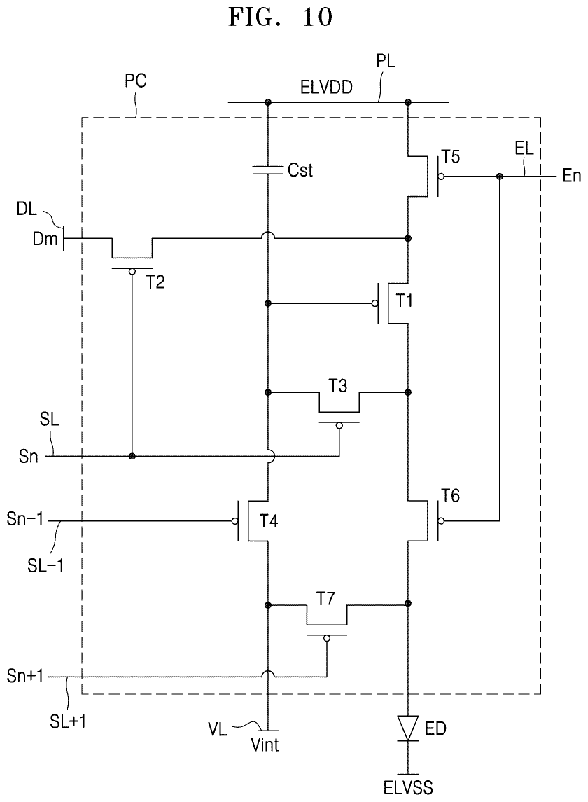

FIGS. 9 and 10 are circuit diagrams each schematically showing a circuit of the display panel 10( [symbol] ) of FIG. 8.

Referring to FIGS. 9 and 10, the pixel circuit PC may be connected to a light-emitting element ED to realize light emission of sub-pixels. The pixel circuit PC includes a driving thin-film transistor T1, a switching thin-film transistor T2, and a storage capacitor Cst. The switching thin-film transistor T2 is connected to a scan line SL and a data line DL and configured to deliver, to the driving thin-film transistor T1, a data signal Dm input through the data line DL, according to a scan signal Sn input through the scan line SL.

The storage capacitor Cst is connected to the switching thin-film transistor T2 and a driving voltage line PL, and stores a voltage corresponding to the difference between a voltage received from the switching thin-film transistor T2 and a driving voltage ELVDD supplied to the driving voltage line PL.

The driving thin-film transistor T1 may be connected to the driving voltage line PL and the storage capacitor Cst, and may control a driving current flowing from the driving voltage line PL to the light-emitting element ED in accordance with a voltage value stored in the storage capacitor Cst. The light-emitting element ED may emit light having a certain brightness according to the driving current.

Although FIG. 9 illustrates that the pixel circuit PC includes two thin-film transistors and one storage capacitor, the disclosure is not limited thereto.

Referring to FIG. 10, the pixel circuit PC may include the driving thin-film transistor T1, the switching thin-film transistor T2, a compensation thin-film transistor T3, a first initialization thin-film transistor T4, an operation-control thin-film transistor T5, an emission control thin-film transistor T6, and a second initialization thin-film transistor T7.

Although FIG. 10 illustrates that each pixel circuit PC includes signal lines SL, SL−1, SL+1, EL, and DL, an initialization voltage line VL, and the driving voltage line PL, the disclosure is not limited thereto. As another embodiment, at least one of the signal lines SL, SL−1, SL+1, EL, and DL, and/or the initialization voltage line VL may be shared by neighboring pixel circuits.

A drain electrode of the driving thin-film transistor T1 may be electrically connected to the light-emitting element ED via the emission control thin-film transistor T6. The driving thin-film transistor T1 receives the data signal Dm in response to a switching operation of the switching thin-film transistor T2 and supplies a driving current to the light-emitting element ED.

A gate electrode of the switching thin-film transistor T2 is connected to the scan line SL, and a source electrode of the switching thin-film transistor T2 is connected to the data line DL. A drain electrode of the switching thin-film transistor T2 may be connected to the driving voltage line PL via the operation control thin-film transistor T5 while being connected to a source electrode of the driving thin-film transistor T1.

The switching thin-film transistor T2 may be turned on in response to the scan signal Sn received through the scan line SL and may perform a switching operation of transferring the data signal Dm received via the data line DL to the source electrode of the driving thin-film transistor T1.

A gate electrode of the compensation thin-film transistor T3 may be connected to the scan line SL. A source electrode of the compensation thin-film transistor T3 may be connected to a pixel electrode of the light-emitting element ED via the emission control thin-film transistor T6 while being connected to the drain electrode of the driving thin-film transistor T1. A drain electrode of the compensation thin-film transistor T3 may be connected together to any one electrode of the storage capacitor Cst, a source electrode of the first initialization thin-film transistor T4, and a gate electrode of the driving thin-film transistor T1. The compensation thin-film transistor T3 is turned on in response to the scan signal Sn received through the scan line SL and connect the gate electrode and the drain electrode of the driving thin-film transistor T1 to each other to diode-connect the driving thin-film transistor T1.

A gate electrode of the first initialization thin-film transistor T4 may be connected to a previous scan line SL−1. A drain electrode of the first initialization thin-film transistor T4 may be connected to the initialization voltage line VL. A source electrode of the first initialization thin-film transistor T4 may be connected together to any one electrode of the storage capacitor Cst, the drain electrode of the compensation thin-film transistor T3, and the gate electrode of the driving thin-film transistor T1. The first initialization thin-film transistor T4 may be turned on in response to a previous scan signal Sn−1 received through the previous scan line SL−1 and configured to transmit an initialization voltage Vint to the gate electrode of the driving thin-film transistor T1 to perform an initialization operation of initializing a voltage of the gate electrode of the driving thin-film transistor T1.

A gate electrode of the operation control thin-film transistor T5 may be connected to an emission control line EL. A source electrode of the operation control thin-film transistor T5 may be connected to the driving voltage line PL. A drain electrode of the operation control thin-film transistor T5 may be connected to the source electrode of the driving thin-film transistor T1 and the drain electrode of the switching thin-film transistor T2.

A gate electrode of the emission control thin-film transistor T6 may be connected to the emission control line EL. A source electrode of the emission control thin-film transistor T6 may be connected to the drain electrode of the driving thin-film transistor T1 and the source electrode of the compensation thin-film transistor T3. A drain electrode of the emission control thin-film transistor T6 may be electrically connected to the pixel electrode of the light-emitting element ED. The operation control thin-film transistor T5 and the emission control thin-film transistor T6 are simultaneously turned on in response to an emission control signal En received through the emission control line EL, the driving voltage ELVDD is transmitted to the light-emitting element ED, and a driving current flows through the light-emitting element ED.

A gate electrode of the second initialization thin-film transistor T7 may be connected to the following scan line SL+1. A source electrode of the second initialization thin-film transistor T7 may be connected to the pixel electrode of the light-emitting element ED. A drain electrode of the second initialization thin-film transistor T7 may be connected to the initialization voltage line VL. The second initialization thin-film transistor T7 may be turned on in response to the following scan signal Sn+1 received through the following scan line SL+1 to initialize the pixel electrode of the light-emitting element ED.

Although FIG. 10 illustrates a case in which the first initialization thin-film transistor T4 and the second initialization thin-film transistor T7 are respectively connected to the previous scan line SL−1 and the following scan line SL+1, the disclosure is not limited thereto. As another embodiment, both of the first initialization thin-film transistor T4 and the second initialization thin-film transistor T7 may be connected to the previous scan line SL-1 to be driven according to the previous scan signal Sn−1.

The other electrode of the storage capacitor Cst may be connected to the driving voltage line PL. Any one electrode of the storage capacitor Cst may be connected together to the gate electrode of the driving thin-film transistor T1, the drain electrode of the compensation thin-film transistor T3, and the source electrode of the first initialization thin-film transistor T4.

An opposite electrode (for example, a cathode) of the light-emitting element ED receives a common voltage ELVSS. The light-emitting element ED receives a driving current from the driving thin-film transistor T1 to emit light.

The pixel circuit PC is not limited to the numbers of thin-film transistors and storages capacitors and the circuit design described with reference to FIGS. 9 and 10, and the numbers of thin-film transistors and storages capacitors and the circuit design may be variously changed.

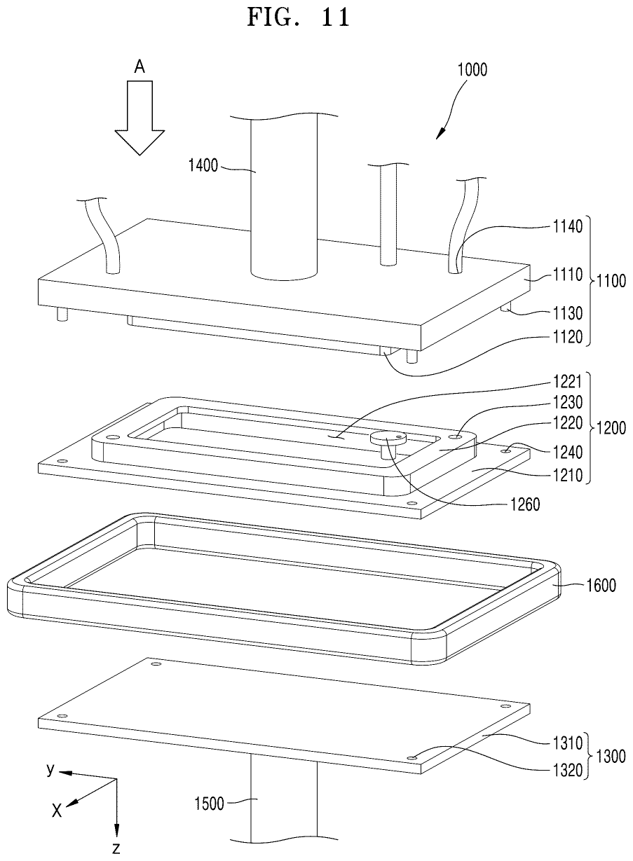

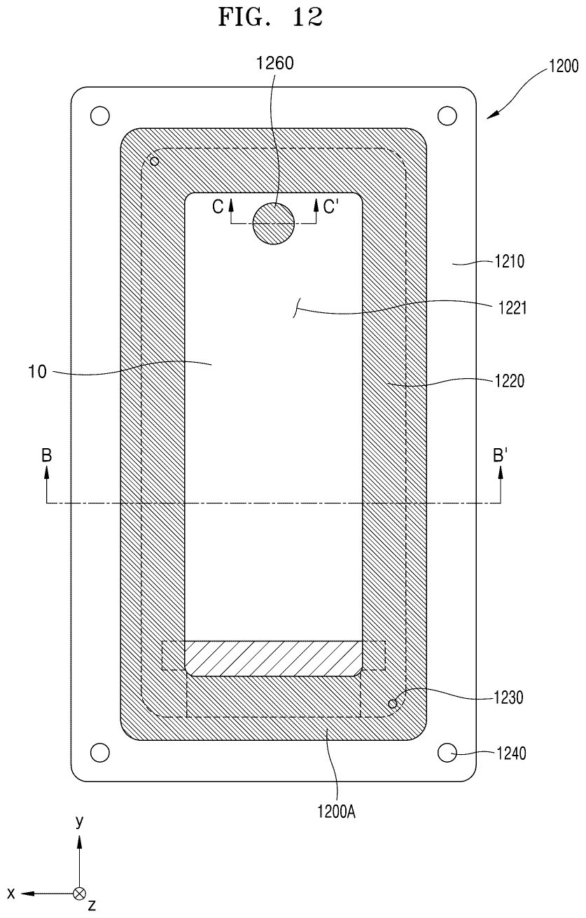

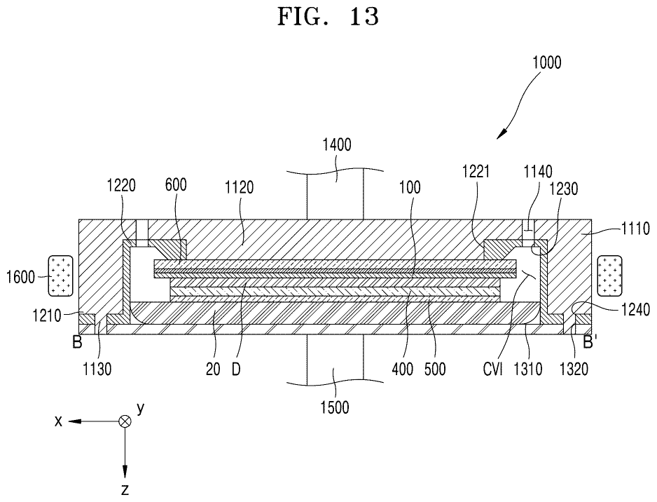

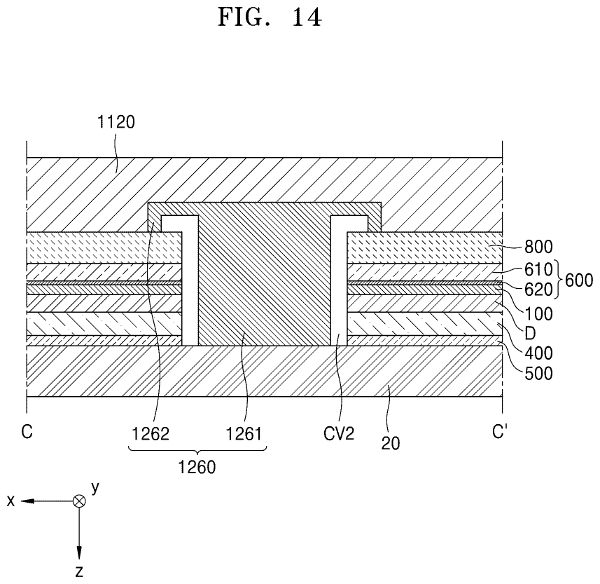

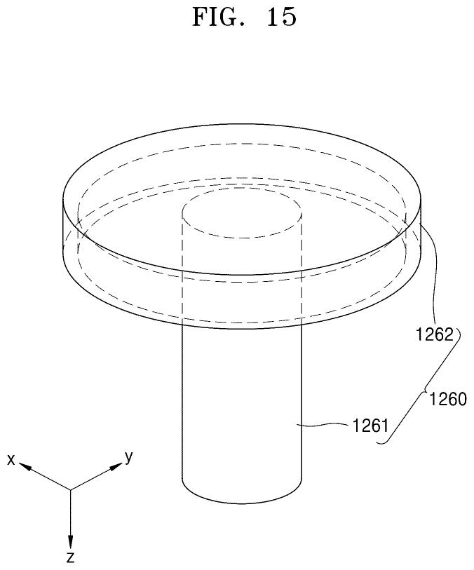

FIG. 11 is a schematic perspective view of a manufacturing apparatus of a display apparatus according to an embodiment. FIG. 12 is a schematic diagram of a manufacturing apparatus of a display apparatus, viewed in a direction A, according to an embodiment. FIG. 12 mainly illustrates a mold in particular. FIG. 13 is a cross-sectional view of the manufacturing apparatus of a display apparatus taken along line B-B′ of FIG. 12, according to an embodiment. FIG. 14 is a cross-sectional view of the manufacturing apparatus of a display apparatus taken along line C-C′ of FIG. 12, according to an embodiment. FIG. 15 is a schematic perspective view of a second mold according to an embodiment.

Referring to FIGS. 11 to 15, a manufacturing apparatus 1000 of a display apparatus may include a first jig 1100, a mold 1200, a second jig 1300, a driver (not shown), and a light source unit 1600.

The first jig 1100 may include a first jig body 1110, a pressurizing unit 1120, a coupling unit 1130, and a first injection unit 1140. The pressurizing unit 1120 may protrude from the first jig body 1110. The pressurizing unit 1120 may be in contact with a portion of the display panel 10 to apply force to the portion of the display panel 10. The coupling unit 1130 may protrude from the first jig body 1110. In this case, the coupling unit 1130 may be formed in a form of a pin to protrude from the first jig body 1110. In this case, a plurality of coupling units 1130 may be provided, and the plurality of coupling units 1130 may be disposed at corner portions of the first jig body 1110 to be spaced apart from each other. The first injection unit 1140 may be disposed on the first jig body 1110. In this case, at least one first injection unit 1140 may be provided, and when a plurality of first injection units 1140 are provided, the plurality of first injection units 1140 may be disposed to be spaced apart from each other. The first injection unit 1140 may be connected to a separate supply unit and pipe that supplies a photocurable resin from the outside or may be inserted with a nozzle that sprays a photocurable resin.

The mold 1200 may move together with the first jig 1100 or may be coupled with the first jig 1100. The mold 1200 may include a mold body 1210, a first mold 1220, a second mold 1260, a second injection unit 1230, and a first accommodation portion 1240. The mold body 1210 may be in a form of a plate and may be in close contact with the second jig 1300 to selectively contact the second jig 1300. The first mold 1220 may protrude toward the first jig 1100 from the mold body 1210. The first mold 1220 may include a mold opening 1221, and the pressurizing unit 1120 may be inserted into the mold opening 1221. In this case, the pressurizing unit 1120 may pass through the mold opening 1221 to be in contact with the display panel 10, for example, the second surface, which is a rear surface, of the display panel 10. The second injection unit 1230 may be disposed to correspond to the first injection unit 1140. The second injection unit 1230 may be disposed on the first mold 1220. The first accommodation portion 1240 may be disposed to correspond to the coupling unit 1130. In this case, the first accommodation portion 1240 may be in a form of a hole.

The second mold 1260 may be disposed inside the mold opening 1221 defined by the first mold 1220. That is, in a plan view, the second mold 1260 may be disposed within the periphery of the first mold 1220 that is formed as a closed loop. As described above, the first mold 1220 may be a mold configured to inject resin into the edge of the display panel 10, and the second mold 1260 may be a mold configured to inject resin into the opening portion 10OP of the display panel 10.

In an embodiment, the second mold 1260 may include a shaft 1261 and a lid 1262. The shaft 1261 may extend in one direction, for example, a third direction (z direction). Here, the z direction may be referred to as a “vertical direction”. That is, the shaft 1261 may protrude toward the first jig 1100 from the mold body 1210. A width of the shaft 1261 in a direction perpendicular to the z direction may be smaller than the width of the opening portion 10OP (or the opening area OA) in the same direction. The lid 1262 may include a flat portion and a protruding portion protruding from the flat portion into the display panel 10. The flat portion of the lid 1262 may be in contact with and connected to an end portion of the shaft 1261, for example, an upper surface (a surface in a +z direction, see the dotted line in FIG. 14). A flat surface of the flat portion of the lid 1262 may be in contact with and connected to the upper surface of the shaft 1261 in FIG. 14, and an inner side surface of the protruding port of the lid 1262 may be spaced apart from an outer peripheral surface of the shaft 1261 to surround the outer peripheral surface of the shaft 1261. In this case, a length of the inner side surface of the protruding portion of the lid 1262 in the third direction may be less than a length of the shaft 1261 in the third direction, that is, an extended length of the shaft 1261. While the protruding portion of the lid 1262 may be in contact with the cushion layer 800, the flat surface of the flat portion may not be in contact with the cushion layer 800. A width of the inner side surface of the protruding portion in a direction perpendicular to the z direction may be greater than the width of the opening portion 10OP (or the opening area OA) in the same direction. Accordingly, the second mold 1260 may form a space (i.e., CV2) along the inner surface of the opening portion 10OP of the display panel 10, and a resin may be injected into the space.

The second jig 1300 may include a second jig body 1310 in a form of a plate and a second accommodation portion 1320 into which the coupling unit 1130 is inserted. The second accommodation portion 1320 may be disposed in the second jig body 1310 to correspond to the coupling unit 1130 and the first accommodation portion 1240. In this case, the second accommodation portion 1320 may be in a form into which a portion of the coupling unit 1130 protruding through the first accommodation portion 1240 is inserted.

The driver may be connected to at least one of the first jig 1100 and the second jig 1300 to linearly move at least one of the first jig 1100 and the second jig 1300. For example, the driver may be connected to the first jig 1100 and bring the first jig 1100 to be closer to the second jig 1300 or to be away from the second jig 1300. As another embodiment, the driver may be connected to the second jig 1300 and bring the second jig 1300 to be closer to the first jig 1100 or to be away from the first jig 1100. As another embodiment, the driver may include a first driver 1400 connected to the first jig 1100 and a second driver 1500 connected to the second jig 1300. Hereinafter, for convenience of description, a case in which the driver includes the first driver 1400 and the second driver 1500 is mainly described in detail.

The driver may be formed in various forms. For example, the driver may include a cylinder. As another embodiment, the driver may include a linear motor. As another embodiment, the driver may also include a motor and a ball screw connected to the motor. In this case, the driver is not limited thereto, and may include all devices and all structures that are connected to at least one of the first jig 1100 and the second jig 1300 to move at least one of the first jig 1100 and the second jig 1300.

The light source unit 1600 may be disposed on the side surface of the display panel 10 to irradiate light toward the display panel 10. In this case, the light source unit 1600 may emit visible light to the outside. In particular, the light source unit 1600 may supply light in a range of a wavelength peak top value of 450 nm or more and 500 nm or less. The light source unit 1600 may be in various forms. For example, the light source unit 1600 may be in a form of a point light source. As another embodiment, the light source unit 1600 may be disposed on a portion of the side surface of the display panel 10 and may also be formed in a linear shape. The light source unit 1600 may also be disposed to entirely surround the side surface of the display panel 10.

Referring to an operation of the manufacturing apparatus 1000 of a display apparatus, after the display panel 10 is disposed on the second jig 1300, the first jig 1100 and the mold 1200 may be disposed on the display panel 10. In this case, at least one of the first driver 1400 and the second driver 1500 may dispose the first jig 1100 and the second jig 1300 to be spaced apart from each other. In addition, the mold 1200 may be coupled to the first jig 1100, or the mold 1200 may be disposed separately on the display panel 10. In this case, the mold 1200 and the second jig 1300 may be disposed so that the first accommodation portion 1240 and the second accommodation portion 1320 correspond to each other.

At least one of the first driver 1400 and the second driver 1500 may operate to bring the first jig 1100 and the second jig 1300 close together. In this case, the first jig 1100 may be in close contact with the second jig 1300. The first jig 1100, for example, the pressurizing unit 1120, may be inserted into the mold opening 1221 to be in contact with the display panel 10 and apply force to the display panel 10, so that the display panel 10 may be prevented from moving. In addition, the coupling unit 1130 may be inserted into the first accommodation portion 1240 and the second accommodation portion 1320 to prevent the mold 1200 from moving, and may prevent the first jig 1100 and the second jig 1300 from moving relative to each other.

When the above process is completed, the mold 1200, the second jig 1300, and the display panel 10 may form a first space CV1 and a second space CV2. The first space CV1 is a space formed by the first mold 1220 and may be formed along the periphery of the display panel 10. The second space CV2 is a space formed by the second mold 1260 and may be formed in the opening portion 10OP of the display panel 10. A photocurable resin may be injected into the first space CV1 through the first injection unit 1140 and the second injection unit 1230, which communicate with the first space CV1. In addition, a photocurable resin may be injected into the second space CV2 through a corresponding injection unit, which communicates with the second space CV2.

Thereafter, light may be irradiated from the light source unit 1600 to the entire side surfaces of the first jig 1100 and the mold 1200 to cure the photocurable resin. In this case, each of the first jig 1100 and the mold 1200 may include a transparent material. For example, the first jig 1100 may include at least one of PMMA, polycarbonate (PC), glass, and quartz, which is a transparent material. In addition, the mold 1200 may have a certain degree of stretchability, and may include at least one of silicon rubber, plastic rubber, and Teflon rubber.

When curing of the photocurable resin is completed through irradiation of light, at least one of the first driver 1400 and the second driver 1500 may operate to separate the first jig 1100 and the second jig 1300. In this case, the mold 1200 may move together with the first jig 1100 to be separated from the second jig 1300, or the first jig 1100 may be separated from the mold 1200 and then the mold 1200 may be removed separately.

The coupling unit 1130 is described above as being provided in the first jig 1100, but the disclosure is not limited thereto. As another embodiment, the coupling unit 1130 may be disposed on the second jig 1300, and the second accommodation portion 1320 may be disposed in the first jig 1100. As another embodiment, the coupling unit 1130 may be disposed on the mold 1200, the first accommodation portion 1240 may be disposed in the first jig 1100, and the second accommodation portion 1320 may be disposed in the second jig 1300. In this case, the coupling unit 1130 of the mold 1200 may include a first coupling unit (not shown) protruding toward the first jig 1100 and a second coupling unit (not shown) protruding toward the second jig 1300.

Hereinafter, a method of forming a first resin structure (not shown) and a second resin structure (not shown) is described in detail.

The first mold 1220 may be disposed to surround the edge, that is, edges, of the display panel 10. The first mold 1220 may form the first space CV1 at the edge, that is, edges, of the display panel 10. The second mold 1260 may be disposed in the opening portion 10OP of the display panel 10. The shaft 1261 of the second mold 1260 may be inserted into opening portion 10OP on the second surface of the display panel 10. In this case, a lower end of the side surface of the lid 1262 in FIG. 14 may be in contact with the cushion layer 800. That is, the lid 1262 may cover the opening area OA of the display panel 10 and a portion of the middle area MA. The second mold 1260 may form the second space CV2 in the opening area OA, that is, the opening portion 10OP.

Next, after the first jig 1100, the mold 1200, and the second jig 1300 are coupled to each other, a photocurable resin may be injected into the first space CV1 and the second space CV2. In this case, in an embodiment, resins injected into the first space CV1 and the second space CV2 may be different from each other.

Thereafter, the light source unit 1600 may irradiate light to the side surface of the display panel 10 from the outside of the first jig 1100 and the mold 1200. The light may cure the photocurable resin disposed in the first space CV1 and the second space CV2.

In this case, the photocurable resin disposed in the first space CV1 may form the first resin structure 30, and the photocurable resin disposed in the second space CV2 may form the second resin structure 40.

According to embodiments of the disclosure, damage to a display panel may be prevented by protecting edges of the display panel.

In addition, damage to an opening portion of the display panel may be prevented.

Effects of the disclosure are not limited to the effects mentioned above, and other effects not mentioned will be clearly understood by one of ordinary in the art from the description of the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel comprising an opening area having an opening portion, a display area at least partially surrounding the opening area, and a middle area positioned between the opening area and the display area;
a cover window disposed to cover a first surface of the display panel;
a first resin structure disposed on a second surface of the display panel along a periphery of the display panel, wherein the second surface includes a side surface of the display panel and a surface of the display panel opposite to the first surface; and
a second resin structure disposed inside the opening portion.

2. The display apparatus of claim 1, wherein, in a plan view, the second resin structure is disposed inside an inner periphery of the first resin structure.

3. The display apparatus of claim 1, wherein, in a plan view, the second resin structure is disposed in a ring shape along an inner surface of the display panel, and the inner surface of the display panel defines the opening portion.

4. The display apparatus of claim 1, wherein the second resin structure comprises
a first portion disposed on an inner surface of the display panel, the inner surface defining the opening portion, and
a second portion extending from the first portion to an outside of the opening area to cover the middle area.

5. The display apparatus of claim 4, wherein the first portion is provided in a cylindrical shape, and the second portion is provided in a ring shape.

6. The display apparatus of claim 1, wherein the second resin structure comprises a different material from a material of the first resin structure.

7. The display apparatus of claim 1, wherein the display panel further comprises:
an image generating layer, which emits light to display an image; and
an optical functional layer disposed on an upper portion of the image generating layer, and
wherein the second resin structure is adhered to an inner surface of the optical functional layer, and the inner surface of the optical functional layer defines the opening portion.

8. The display apparatus of claim 7, wherein the optical functional layer comprises
a first protective layer, a second protective layer, and a polarizing layer between the first protective layer and the second protective layer, and
wherein the second resin structure is adhered to an inner surface of the polarizing layer, and the inner surface of the polarizing layer defines the opening portion.

9. The display apparatus of claim 8, wherein the second resin structure is adhered to the inner surface of the polarizing layer by hydrogen bonding.

10. The display apparatus of claim 1, wherein the second resin structure comprises an acrylic material.

11. The display apparatus of claim 10, wherein an adhesive strength of the second resin structure is 10 newtons per square centimeters (N/cm²) to 50 N/cm².

12. A manufacturing apparatus comprising:
a first jig;
a second jig on which a display panel having an opening portion is mounted and disposed to face the first jig;
a first mold disposed between the first jig and the second jig, selectively coupled to the first jig, and forming a first space outside an edge portion of the display panel together with the second jig so that a resin is injected into the first space; and
a second mold forming a second space inside the opening portion so that a resin is injected into the second space.

13. The manufacturing apparatus of claim 12, wherein the second mold comprises
a shaft extending in a vertical direction, and
a lid having a flat surface connected to an upper surface of the shaft and a side surface spaced apart from and surrounding an outer peripheral surface of the shaft.

14. The manufacturing apparatus of claim 13, wherein a length of the shaft in the vertical direction is greater than a length of the side surface of the lid in the vertical direction.

15. The manufacturing apparatus of claim 12, wherein the second mold is disposed inside an edge of the first mold formed into a closed loop in a plan view.

16. A method of manufacturing a display apparatus, the method comprising:
disposing, on a second jig spaced apart from a first jig, a display panel having an opening portion;
forming a space in and outside the display panel by disposing the first jig and a mold on the display panel;
supplying a photocurable resin into the space; and
curing the photocurable resin by irradiating light into the space,
wherein the mold comprises a first mold surrounding an edge portion of the display panel to form a first space and a second mold forming a second space in the opening portion, and the space includes the first space and the second space.

17. The method of claim 16, wherein the second mold comprises
a shaft extending in a vertical direction, and
a lid having a flat surface connected to an upper surface of the shaft and a side surface spaced apart from and surrounding an outer peripheral surface of the shaft.

18. The method of claim 16, wherein a photocurable resin supplied to the first space is different from a photocurable resin supplied to the second space.

19. The method of claim 16, wherein an adhesive strength of a photocurable resin supplied to the second space is 10 N/cm² to 50 N/cm².

20. An electronic device comprising:
the display apparatus of claim 1; and
a housing accommodating the display apparatus.
